(19) United States
(12) Patent Application Publication
(10) Pub. No.: US 2006/0257752 A1
(43) Pub. Date: Nov. 16, 2006

(54) PHASE SHIFT MASK FOR PREVENTING HAZE

(75) Inventors: Yong Dae Kim, Chungcheongnam-do (KR); Jong Min Kim, Daejon (KR); Han Byul Kang, Gyeonggi-do (KR); Hyun Joon Cho, Gyeonggi-do (KR); Sang Soo Choi, Daejon (KR)

Correspondence Address: ADAM K. SACHAROFF;MUCH SHELIST FREED DENENBERG AMENT&RUBENSTEIN,PC, 191 N. WACKER DRIVE, SUITE 1800, CHICAGO, IL, 60606-1615, US

(73) Assignee: PKL CO., Ltd., Chungcheongnam-do (KR)

(21) Appl. No.: 11/277,182

(22) Filed: Mar. 22, 2006

(30) Foreign Application Priority Data
May 16, 2005 (KR) 10-2005-0040499

(51) Int. Cl. G03F 1/00

(52) U.S. Cl. 430/5

(57) ABSTRACT

Disclosed is a phase shift mask. Residual ions, which are considered a factor of occurrence of haze which is a growth defect of a surface of a photomask during a photolithography step of a wafer process, are controlled in order to change the content of a surface of the phase shift mask. Diffusion of the residual ions into the surface of the mask is suppressed during a photomask wet cleaning process in order to prevent the haze.

### BACKGROUND OF THE INVENTION

1. Field of the Invention

The present invention relates, in general, to a phase shift mask and, more particularly, to a phase shift mask in which a patterned lightproof film (MoSiON) is heat treated in order to prevent haze from forming.

2. Description of the Related Art

In accordance with an increase in the integration of devices in a semiconductor process, the wavelengths of exposure sources are becoming shorter and shorter in order to improve the resolution of a pattern. Accordingly, haze, which does not form in a conventional wavelength band, may occur. The reason is as follows. In a conventional photolithography process at a wavelength above an I-line, exposing energy is relatively low, thus a phenomenon in which residual ions, such as SOₓ, NOₓ, POₓ, F, Cl, NH₄, Ca, and Mg, on the surface of a photomask cause an optical reaction does not occur.

However, at a light source of 248 nm or less, exposing energy is increased as the wavelength is shortened. Therefore, an optical reaction occurs between the residual ions on the surface of the mask, and a growth defect called a haze is formed.

FIG. 1 illustrates a phase shift mask in which a conventional lightproof film (MoSiON) is patterned, and FIG. 2 is a graph showing AUGER analysis results of the conventional lightproof film (MoSiON).

With reference to FIGS. 1 and 2, after a lightproof film (MoSiON) 11 as a phase shift film is patterned on a transparent substrate 10, the conventional phase shift mask is subjected to a wet cleaning process in order to prevent a haze from occurring, and a compositional ratio of the lightproof film (MoSiON) 11 is then subjected to an AUGER analysis. From the results of the analysis, it can be seen that there is little change in a silicon (Si) composition on the surface and inside the lightproof film (MoSiON).

Conventionally, the wet cleaning process, in which the type and compositional ratio of chemical substances and the temperature are controlled depending on the purpose of the process, is conducted in order to remove haze. However, since it is almost impossible to completely remove residual ions, in order to make up for this, there remains a need to develop a novel process.

Particularly, it is necessary to develop a process in which, after Mo, having high reactivity to ammonia (NH₄), has been used to pattern a phase shift mask, ammonia present on a sidewall is prevented from permeating through the phase shift mask during a wet cleaning process using ammonia.

### SUMMARY OF THE INVENTION

Accordingly, the present invention has been made keeping in mind the above problems occurring in the prior art, and an object of the present invention is to provide a phase shift mask in which a patterned lightproof film (MoSiON) is heat treated in order to suppress the permeation of residual ions contained in a cleaning solution through the phase shift mask during a wet cleaning process, so as to prevent a haze.

In order to accomplish the above object, the present invention provides a phase shift mask. The phase shift mask comprises a lightproof film (MoSiON) as a patterned phase shift film, which is heat treated on a transparent substrate in order to form an oxide film on the surface of the lightproof film (MoSiON).

The present invention is characterized in that a lightproof film (MoSiON) as a patterned phase shift film is heat treated in an oxygen (O₂) atmosphere in order to form an oxide film 22 on the surface of the lightproof film 21 so that residual ions contained in a cleaning solution are prevented from diffusing into a phase shift mask during a wet cleaning process.

It is preferable that the heat treatment be conducted in an electric heating furnace in a gas atmosphere which includes one or more selected from the group consisting of O₂, N₂, Ar, and He at 50-1000° Celsius for 5 min-5 hours. If the heat treatment is conducted using a convection oven, the temperature is preferably 50-400° Celsius.

### BRIEF DESCRIPTION OF THE DRAWINGS

The above and other objects, features and advantages of the present invention will be more clearly understood from the following detailed description taken in conjunction with the accompanying drawings, in which:

FIG. 1 illustrates a phase shift mask in which a conventional lightproof film (MoSiON) is patterned;

FIG. 2 is a graph showing AUGER analysis results of the conventional lightproof film (MoSiON);

FIG. 3 illustrates a phase shift mask in which a lightproof film (MoSiON) is heat treated according to the present invention; and

FIG. 4 is a graph showing AUGER analysis results of the heat treated lightproof film (MoSiON) according to the present invention.

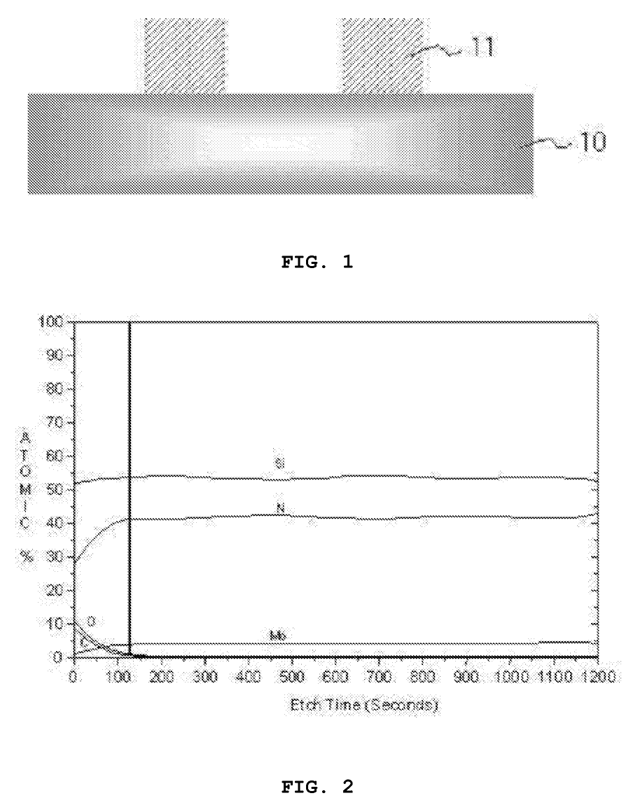

### DESCRIPTION OF THE PREFERRED EMBODIMENTS

Hereinafter, a detailed description will be given of the present invention, referring to the accompanying drawings.

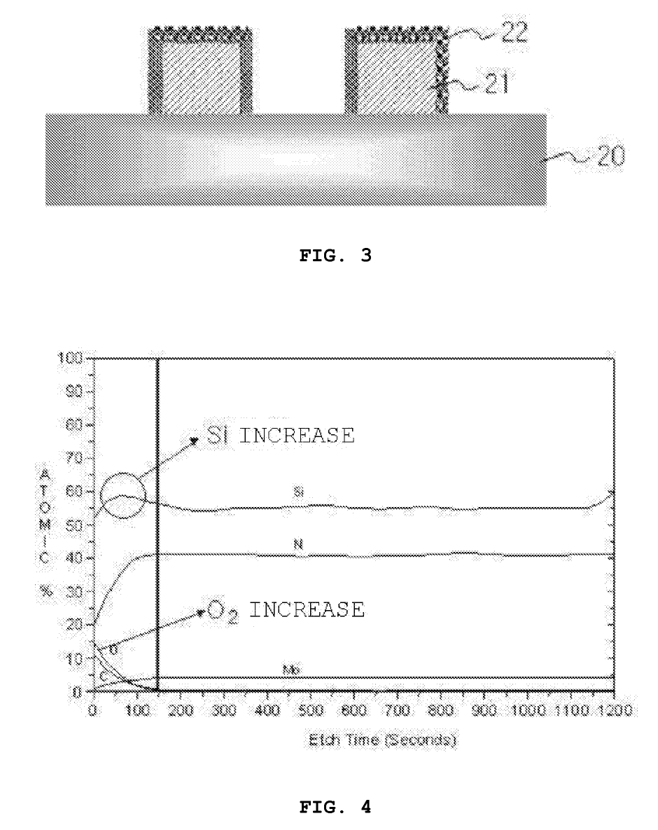

FIG. 3 illustrates a phase shift mask in which a patterned lightproof film (MoSiON) is heat treated according to the present invention, and FIG. 4 is a graph showing AUGER analysis results of a composition of the lightproof film (MoSiON) heat treated in an oxygen atmosphere according to the present invention.

Referring to FIG. 3, a lightproof film (MoSiON) 21 as a phase shift film is patterned on a transparent substrate 20, subjected to a wet cleaning process in order to suppress the occurrence of haze, and heat treated in an oxygen atmosphere to form a novel type of oxide film 22 on the surface of the lightproof film 21.

With reference to FIG. 4, silicon (Si) and oxygen (O₂) are increased within a height of 100 Å from the surface of the MoSiON phase shift film 21, as a result of conducting AUGER analysis of the heat treated lightproof film (MoSiON) 21. This means that Si which is present in MoSiON during heat treatment in an oxygen atmosphere is diffused to an upper part thereof by heat.

Since Si which is present in MoSiON 21 is diffused to the upper part thereof by heat, the content of Mo, which is chemically nonresistant to an ammonia cleaning solution, is reduced. Hence, the diffusion of ammonia ions into the phase shift film is reduced, and silicon (Si), which is increased on the surface of the lightproof film 21, is reacted with oxygen (O₂) to form the oxide film 22 during the wet cleaning process, thereby it is possible to prevent the ions contained in the cleaning solution during the wet cleaning process from being diffused into the phase shift mask.

In connection with this, it is preferable that the heat treatment be conducted in a gas atmosphere which includes one or more selected from N₂, O₂, Ar, and He in an electric heating furnace at 50-1000° Celsius for 5 min-5 hours. When the heat treatment is conducted using a convection oven, it is preferable that the heat treatment be conducted at 50-400° Celsius.

As described above, the present invention is advantageous in that a lightproof film (MoSiON) as a patterned phase shift film is heat treated to diffuse Si present in the lightproof film (MoSiON) into an upper part thereof so that the content of Mo is reduced in order to prevent ammonia ions from diffusing into the phase shift film. Furthermore, silicon (Si), having diffused into the upper part thereof, combines with oxygen (O₂) to form an oxide film, so that the chemical stability of the lightproof film (MoSiON) is increased and a wet cleaning solution and ions in the atmosphere are prevented from permeating through the phase shift film, thereby haze is prevented.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

We claim:

1. A phase shift mask, comprising:
a transparent substrate;
a lightproof film (MoSiON) as a phase shift film patterned on the transparent substrate; and
an oxide film formed on a surface of the lightproof film (MoSiON) as a result of heat treatment of the lightproof film.

2. The phase shift mask as set forth in claim 1, wherein the heat treatment is conducted in an oxygen atmosphere.

3. The phase shift mask as set forth in claim 1, wherein the heat treatment is conducted in a gas atmosphere which includes one or more selected from a group consisting of N₂, Ar, O₂, and He gases.

4. The phase shift mask as set forth in claim 1, wherein the heat treatment is conducted in an electric heating furnace or in a convection oven.

5. The phase shift mask as set forth in claim 1, wherein the heat treatment is conducted at 50-1000° Celsius for 5 min-5 hours.

6. The phase shift mask as set forth in claim 1, wherein the lightproof film (MoSiON) is heat treated to diffuse Si to the surface of the lightproof film (MoSiON) and thus reduce a content of Mo.
